(19) United States
(12) Patent Application Publication
(10) Pub. No.: US 2026/0282587 A1
(43) Pub. Date: Sep. 17, 2026

(54) PHOTODETECTOR

(71) Applicant: SONY SEMICONDUCTOR SOLUTIONS CORPORATION, Kanagawa (JP)

(72) Inventor: Akifumi YAMAMURA, Kanagawa (JP)

(73) Assignee: SONY SEMICONDUCTOR SOLUTIONS CORPORATION, Kanagawa (JP)

(21) Appl. No.: 19/167,901

(22) PCT Filed: Feb. 16, 2024
(86) PCT No.: PCT/JP2024/005581

§ 371 Date: Sep. 23, 2025

(30) Foreign Application Priority Data
Mar. 31, 2023 (JP) 2023-058995

(51) Int. Cl. H10F 39/00; H10W 42/20

(52) U.S. Cl. CPC H10F 39/809; H10F 39/811; H10W 42/271

(57) ABSTRACT

A photodetector according to one embodiment of the present disclosure includes: a first substrate having a first face and a second face opposed to each other, and having a pixel array section; a second substrate stacked on a side of the first face of the first substrate, and having a semiconductor layer with one or more transistors; a light receiving element inside the first substrate for each of the pixels, and having a light receiver and a multiplier, the light receiver generating carriers corresponding to an amount of received light by photoelectric conversion, the multiplier avalanche multiplying the generated carriers; a first contact layer on the first face of the first substrate and electrically coupled to the light receiver; and a shield layer on a path coupling the first contact layer and the one or more transistors, and to which a predetermined potential is to be applied.

### TECHNICAL FIELD

The present disclosure relates to a photodetector including an avalanche photodiode.

### BACKGROUND ART

For example, PTL 1 discloses a single-photon avalanche diode (SPAD) image sensor having a three-layer stacked structure in which transistors that constitute part of a signal processing circuit are formed on pixels and further are bonded to an ASIC circuit chip.

### CITATION LIST

### Patent Literature

PTL 1: US Unexamined Patent Application Publication No. 2018/0308881

### SUMMARY OF THE INVENTION

A photodetector, in which transistors are formed at positions facing pixels as described above, is desired to have improved pixel characteristics.

It is desirable to provide a photodetector that makes it possible to improve pixel characteristics.

A photodetector according to one embodiment of the present disclosure includes: a first substrate having a first face and a second face opposed to each other, and having a pixel array section in which a plurality of pixels is arranged in an array in an in-plane direction; a second substrate stacked on a side of the first face of the first substrate, and having a semiconductor layer provided with one or more transistors; a light receiving element provided inside the first substrate for each of the pixels, and having a light receiver and a multiplier, the light receiver that generates carriers corresponding to an amount of received light by photoelectric conversion, the multiplier that avalanche-multiplies the carriers generated by the light receiver; a first contact layer that is provided on the first face of the first substrate, and is electrically coupled to the light receiver; and a shield layer that is provided on a path coupling the first contact layer and the one or more transistors, and to which a predetermined potential is to be applied.

The photodetector according to one embodiment of the present disclosure includes the shield layer provided on the path coupling the fist contact layer and the one or more transistors. The first contact layer is provided on the first face of the first substrate that includes the light receiving element having the light receiver and the multiplier, and is electrically coupled to the light receiver. The one or more transistors are provided in the semiconductor layer that constitutes the second substrate stacked on the first face. The predetermined potential is to be applied to the shield layer. This suppresses electrical interference caused by a potential difference between the first contact layer and the one or more transistors.

### BRIEF DESCRIPTION OF THE DRAWINGS

FIG. 1 is a schematic cross-sectional diagram illustrating an example of a photodetector according to a first embodiment of the present disclosure.

FIG. 2 is a schematic plan diagram corresponding to a region A and a region B of the photodetector illustrated in FIG. 1.

FIG. 3 is a block diagram illustrating an example of a schematic configuration of the photodetector illustrated in FIG. 1.

FIG. 4 illustrates an example of an equivalent circuit of a unit pixel of the photodetector illustrated in FIG. 1.

FIG. 5 is a schematic diagram illustrating another example of a planar configuration corresponding to the region B of the photodetector illustrated in FIG. 1.

FIG. 6 is a schematic plan diagram illustrating an example of a photodetector according to a second embodiment of the present disclosure.

FIG. 7 is a schematic plan diagram corresponding to the region A and the region B of the photodetector illustrated in FIG. 6.

FIG. 8 is a schematic cross-sectional diagram illustrating an example of a photodetector according to Modification Example 1 of the present disclosure.

FIG. 9 is a schematic plan diagram corresponding to the region B of the photodetector illustrated in FIG. 8.

FIG. 10 is a schematic cross-sectional diagram illustrating an example of a photodetector according to Modification Example 2 of the present disclosure.

FIG. 11 is a schematic plan diagram corresponding to the region B of the photodetector illustrated in FIG. 10.

FIG. 12 is a schematic plan diagram illustrating an example of a photodetector according to Modification Example 3 of the present disclosure.

FIG. 13 is a schematic plan diagram corresponding to the region A and the region B of the photodetector illustrated in FIG. 12.

FIG. 14 is a schematic plan diagram illustrating an example of a photodetector according to Modification Example 4 of the present disclosure.

FIG. 15 is a schematic plan diagram illustrating an example of a photodetector according to Modification Example 5 of the present disclosure.

FIG. 16 is a schematic plan diagram illustrating another example of the photodetector according to Modification Example 5 of the present disclosure.

FIG. 17 is a schematic plan diagram corresponding to the region B of the photodetector illustrated in FIG. 16.

FIG. 18 is a schematic plan diagram illustrating an example of a photodetector according to Modification Example 6 of the present disclosure.

FIG. 19 is a schematic plan diagram illustrating an example of a photodetector according to Modification Example 7 of the present disclosure.

FIG. 20 is a functional block diagram illustrating an example of an electronic device using the photodetector in FIG. 1 and the like.

FIG. 21 is a view depicting an example of a schematic configuration of an endoscopic surgery system.

FIG. 22 is a block diagram depicting an example of a functional configuration of a camera head and a camera control unit (CCU).

FIG. 23 is a block diagram depicting an example of schematic configuration of a vehicle control system.

FIG. 24 is a diagram of assistance in explaining an example of installation positions of an outside-vehicle information detecting section and an imaging section.

### MODES FOR CARRYING OUT THE INVENTION

The following is a detailed description of embodiments of the present disclosure with reference to the drawings. The following description is one specific example of this disclosure, and the present disclosure is not limited to the following embodiments. The present disclosure is not limited to the arrangement, dimensions, dimensional ratios, and the like of the components illustrated in the drawings. It is to be noted that description is given in the following order.
1. First Embodiment (A photodetector having a shield layer on a path coupling an anode and transistors)
2. Second Embodiment (A photodetector having a shield layer on a path coupling a multiplication region and transistors)
3. Modification Examples
3-1. Modification Example 1 (Another example of a configuration of the photodetector)
3-2. Modification Example 2 (Another example of the configuration of the photodetector)
3-3. Modification Example 3 (Another example of the configuration of the photodetector)
3-4. Modification Example 4 (Another example of the configuration of the photodetector)
3-5. Modification Example 5 (Another example of the configuration of the photodetector)
3-6. Modification Example 6 (Another example of the configuration of the photodetector)
3-7. Modification Example 7 (Another example of the configuration of the photodetector)
4. Application Examples
5. Practical Application Examples

### 1. FIRST EMBODIMENT

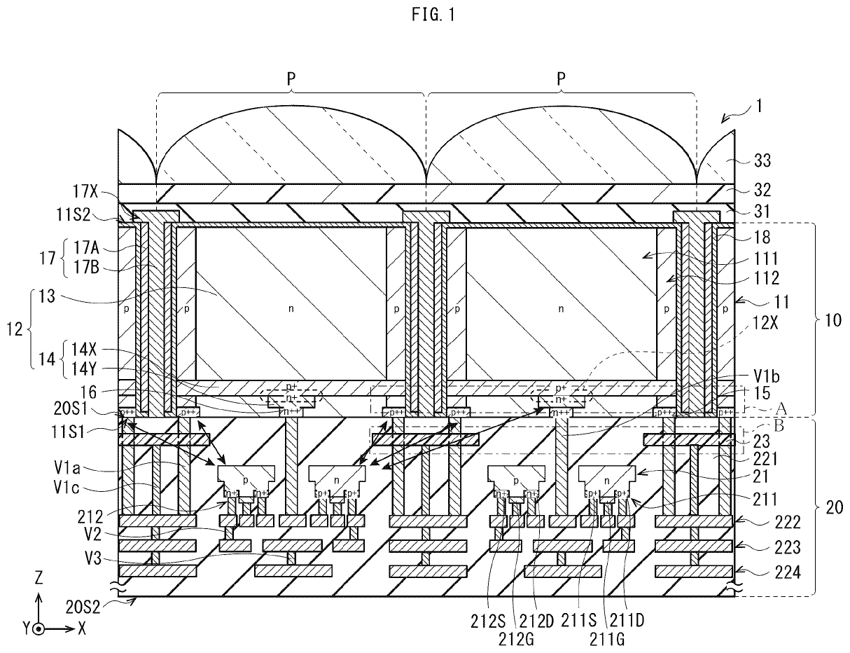

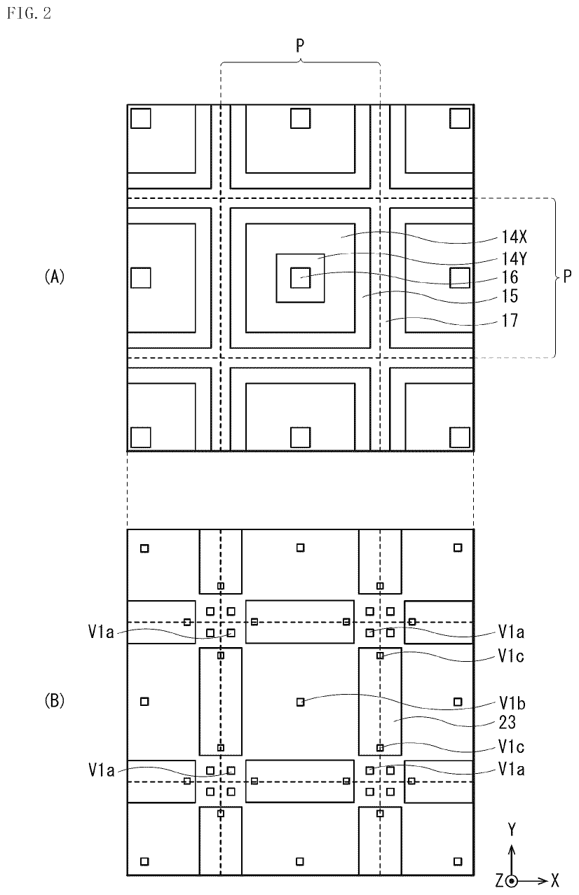

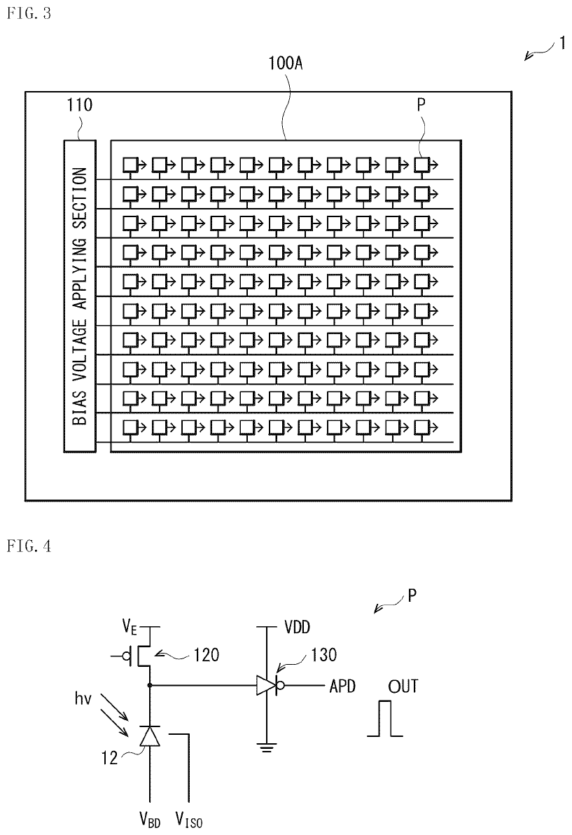

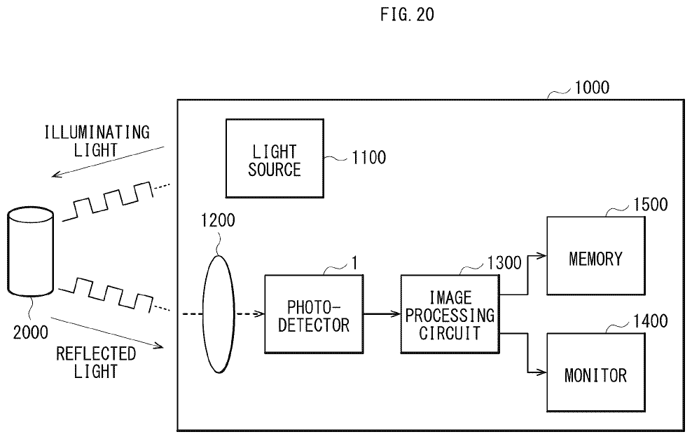

FIG. 1 schematically illustrates an example of a cross-sectional configuration of a photodetector (a photodetector 1) according to a first embodiment of the present disclosure. FIG. 2(A) schematically illustrates a planar configuration corresponding to a region A of the photodetector 1 illustrated in FIG. 1. FIG. 2(B) schematically illustrates a planar configuration corresponding to a region B of the photodetector 1 illustrated in FIG. 1. FIG. 3 is a block diagram illustrating a schematic configuration of the photodetector 1 illustrated in FIG. 1, and FIG. 4 illustrates an example of an equivalent circuit of a unit pixel P of the photodetector 1 illustrated in FIG. 1. The photodetector 1 is applicable to, for example, a range imaging sensor (e.g., a range imaging device 1000, see FIG. 20) that measures a distance by a Time-of-Flight (ToF) method, an image sensor, and the like.

### Configuration of Photodetector

For instance, the photodetector 1 has a pixel array section 100A in which a plurality of unit pixels P is arranged in an array in row and column directions. As illustrated in FIG. 3, the photodetector 1 includes a bias voltage applying section 110 along with the pixel array section 100A. The bias voltage applying section 110 applies a bias voltage to each unit pixel P in the pixel array section 100A. The present embodiment describes a case where electrons are read out as signal charges.

As illustrated in FIG. 4, each unit pixel P includes a light receiving element 12, a quenching resistor 120 including, for example, a p-type metal-oxide-semiconductor field-effect transistor (MOSFET), and an inverter 130 including, for example, a complementary MOSFET.

The light receiving element 12 converts the incident light into an electrical signal by photoelectric conversion and outputs the electrical signal. Specifically, the light receiving element 12 converts the incident light (a photon) into an electrical signal by photoelectric conversion, and outputs a pulse in response to the incidence of the photon. For instance, the light receiving element 12 is a single photon avalanche diode (SPAD) device. The SPAD device has, for example, a characteristic in which an avalanche multiplication region 12X (a depletion layer) is formed by a large negative voltage applied to a cathode, and electrons generated in response to the incidence of a single photon causes avalanche multiplication and a large current flows. For instance, the light receiving element 12 has an anode coupled to the bias voltage applying section 110 and a cathode coupled to a source terminal of the quenching resistor 120. A device voltage VB is applied to the anode of the light receiving element 12 from the bias voltage applying section 110.

The quenching resistor 120 is coupled in series with the light receiving element 12, with the source terminal coupled to the cathode of the light receiving element 12 and the drain terminal coupled to a power supply not illustrated. An excitation voltage VE is applied to the drain terminal of the quenching resistor 120 from the power supply. When a voltage of electrons avalanche-multiplied by the light-receiving element 12 reaches a negative voltage VBD, the quenching resistor 120 performs quenching in which the electrons multiplied by the light-receiving element 12 are emitted to return the voltage to an initial voltage.

The inverter 130 has its input terminal coupled to the cathode of the light receiving element 12 and the source terminal of the quenching resistor 120, and its output terminal coupled to a subsequent arithmetic processing section. The inverter 130 outputs a light receiving signal on the basis of the carriers (signal charges) multiplied by the light receiving element 12. More specifically, the inverter 130 shapes the voltage generated by the electrons multiplied by the light receiving element 12. Then, the inverter 130 outputs a light receiving signal (APD OUT) in which, for example, a pulse waveform illustrated in FIG. 4 is generated to the arithmetic processing section with an arrival time of one font as a starting point. For instance, the arithmetic processing section calculates a distance to a subject on the basis of a timing of generation of the pulse indicating the arrival time of one font for each light-receiving signal, thus finding the distance for each unit pixel P. Then, on the basis of these distances, a distance image is generated in which the distances to the subject detected by a plurality of unit pixels P are arranged in a planar manner.

For instance, the photodetector 1 is a back-illuminated photodetector that includes a logic substrate 20 stacked on a front surface of a sensor substrate 10 (e.g., a front surface (a first face 11S1) of a semiconductor substrate 11 constituting the sensor substrate 10) and receives light from a rear surface of the sensor substrate 10 (e.g., a rear surface (a second face 11S2) of the semiconductor substrate 11 constituting the sensor substrate 10).

The photodetector 1 has the light receiving element 12 for each unit pixel P. The light receiving element 12 has a light receiver 13 and a multiplier 14. As described above, the photodetector 1 has the sensor substrate 10 and the logic substrate 20 that are stacked together.

The sensor substrate 10 includes the semiconductor substrate 11 including, for example, a silicon substrate, and the light receiver 13 and the multiplier 14 are embedded in the semiconductor substrate 11, for example. The semiconductor substrate 11 includes a contact layer 15 (anode) and a contact layer 16 (cathode) on its first face 11S1. The contact layer 15 is electrically coupled to the light receiver 13, and the contact layer 16 is electrically coupled to the multiplier 14. The semiconductor substrate 11 further includes a pixel separator 17 that electrically separates adjacent unit pixels P. The pixel separator 17 is placed between a plurality of unit pixels P adjacent to each other in the row and column directions so as to extend between the first face 11S1 and the second face 11S2 of the semiconductor substrate 11, and is provided in a lattice pattern in a plan view in the entire pixel array section 100A.

For instance, the logic substrate 20 has a semiconductor layer 21 embedded in an interlayer insulating layer 221. In the semiconductor layer 21, a plurality of transistors (e.g., a p-MOS transistor 211 and an n-MOS transistor 212) are formed, which constitute a readout circuit that outputs a pixel signal based on the carrier outputted from the unit pixel P (the light receiving element 12), for example. The logic substrate 20 further has through vias V1a and V1b that penetrate the semiconductor layer 21 in a stacking direction (a Z-axis direction) and are electrically coupled to the contact layers 15 and 16, respectively. In the present embodiment, a shield layer 23, to which a predetermined potential is to be applied, is provided on a path coupling the contact layer 15 and each of the p-MOS transistor 211 and the n-MOS transistor 212.

This sensor substrate 10 corresponds to a specific example of a “first substrate” in one embodiment of the present disclosure, and the logic substrate 20 corresponds to a specific example of a “second substrate” in one embodiment of the present disclosure. The contact layer 15 corresponds to a specific example of a “first contact layer” in one embodiment of the present disclosure, and the contact layer 16 corresponds to a specific example of a “second contact layer” in one embodiment of the present disclosure. The through via V1c corresponds to a specific example of a “through-wire” in one embodiment of the present disclosure. The shield layer 23 corresponds to a specific example of a “shield layer” in one embodiment of the present disclosure.

Note that the symbols “p” and “n” in the drawing represent p-type and n-type semiconductor regions, respectively. The “+” or “−” at the end of “p” represents an impurity concentration of the p-type semiconductor region. Similarly, the “+” or “−” at the end of “n” represents an impurity concentration of the n-type semiconductor region. In the description, the greater the number of “+” signs, the higher the impurity concentration, and the greater the number of “−” signs, the lower the impurity concentration. The same applies to the subsequent drawings.

The semiconductor substrate 11 has the first face 11S1 and second face 11S2 opposed to each other. The semiconductor substrate 11 has a p-well (p) common to the plurality of unit pixels P. The semiconductor substrate 11 is provided, for each of the unit pixels P, with an n-type semiconductor region (n) 111 in which the impurity concentration is controlled to n-type, for example, and the n-type semiconductor region (n) 111 constitutes a light receiver 13. The semiconductor substrate 11 is further provided with a p-type semiconductor region (p⁺) 14X and an n-type semiconductor region (n⁺) 14Y, which constitute the multiplier 14 on a side of the first face 11S1. This makes up a light receiving element 12 for each unit pixel P. The semiconductor substrate 11 is further provided with a pixel separator 17 around each unit pixel P to electrically separate adjacent unit pixels P. Between the light receiving element 12 and the pixel separator 17, a p-type semiconductor region (p) 112 having a higher impurity concentration than the p-well is provided.

The light receiving element 12 has a multiplication region (the avalanche multiplication region 12X) that avalanche-multiplies carriers by a high electric field region. As described above, the light receiving element 12 is a SPAD device that enables the formation of the avalanche multiplication region 12X by a large negative voltage applied to the cathode (the contact layer 16), and is capable of avalanche-multiplying electrons generated by the incidence of one photon.

As described above, the light receiving element 12 has the light receiver 13 and the multiplier 14.

The light receiver 13 corresponds to a specific example of a “light receiver” in one embodiment of the present disclosure, and has a photoelectric conversion function of absorbing light incident through the second face 11S2 of the semiconductor substrate 11 and generating carriers corresponding to the amount of the light received. As described above, the light receiver 13 includes an n-type semiconductor region (n) 111 in which the impurity concentration is controlled to n-type, and carriers generated in the light receiver 13 are transferred to the multiplier 14 by a potential gradient.

The multiplier 14 corresponds to a specific example of a “multiplier” in one embodiment of the present disclosure, and avalanche-multiplies carriers (electrons in the present embodiment) generated in the light receiver 13. For instance, the multiplier 14 includes the p-type semiconductor region (p⁺) 14X having a higher impurity concentration than the p-well (p) and the n-type semiconductor region (n⁺) 14Y having a higher impurity concentration than the n-type semiconductor region (n) 111. The p-type semiconductor region (p⁺) 14X and the n-type semiconductor region (n⁺) 14Y are provided on the side of the first face 11S1, and are stacked in the order of the n-type semiconductor region (n⁺) 14Y and the p-type semiconductor region (p⁺) 14X from the first face 11S1. The p-type semiconductor region (p⁺) 14X has an area in an XY plane direction larger than an area of the n-type semiconductor region (n⁺) 14Y in the XY plane direction, and is placed over the entire surface of the unit pixel P partitioned by the pixel separator 17. The configuration, however, is not limited to this, and the p-type semiconductor region (p⁺) 14X may be formed on an inner side of the p-type semiconductor region (p) 112, for example.

The light receiving element 12 has the avalanche multiplication region 12X formed at a junction between the p-type semiconductor region (p⁺) 14X and the n-type semiconductor region (n⁺) 14Y. The avalanche multiplication region 12X is a high electric field region (a depletion layer) formed at an interface between the p-type semiconductor region (p⁺) 14X and the n-type semiconductor region (n⁺) 14Y by a large negative voltage applied to the cathode. In the avalanche multiplication region 12X, electrons (e⁻) generated by a single photon incident on the light receiving element 12 are multiplied.

The semiconductor substrate 11 is provided with the contact layer 15 and the contact layer 16 on the first face 11S1, and the contact layer 15 includes a p-type semiconductor region (p⁺⁺) that is electrically coupled to the n-type semiconductor region (n) 111 constituting the light receiver 13, and the contact layer 16 includes a n-type semiconductor region (n⁺⁺) that is electrically coupled to the n-type semiconductor region (n⁺) 14Y constituting the multiplier 14. For instance, the contact layer 15 is placed along an inner edge of the unit pixel P. Specifically, as illustrated in FIG. 2(A), the contact layer 15 is placed along the pixel separator 17 to surround the light receiver 13, and is coupled as the anode of the light receiving element 12 to the bias voltage applying section 110. The contact layer 16 is coupled as the cathode to the source terminal of the quenching resistor 120.

The pixel separator 17 electrically separates adjacent unit pixels P, and is provided in a lattice shape in the pixel array section 100A so as to separate the unit pixels P in a plan view, for example. The pixel separator 17 extends between the first face 11S1 and the second face 11S2 of the semiconductor substrate 11, and penetrates the semiconductor substrate 11, for example. For instance, the pixel separator 17 includes an insulating film 17A and a light shielding film 17B embedded in the insulating film 17A. The pixel separator 17 may be provided from the first face 11S1 of the semiconductor substrate 11 or may be formed from the second face 11S2 of the semiconductor substrate 11.

For instance, the insulating film 17A includes silicon oxide (SiOₓ). In one example, the light shielding film 17B includes a metal material having light-shielding properties, such as tungsten (W), aluminum (Al), copper (Cu), cobalt (Co), nickel (Ni), or titanium (Ti), or a silicon compound thereof. In another example, the light shielding film 17B may include polysilicon (Poly-Si). The light-shielding film 17B may include a wide portion 17X formed on the second surface 11S2 of the semiconductor substrate 11 to suppress the incidence of obliquely incident light between adjacent unit pixels P.

On side and bottom faces of the pixel separator 17 and on the second face 11S2 of the semiconductor substrate 11, a layer having a fixed charge (a fixed charge film 18) may be placed, for example. This fixed charge film 18 may be a film having a positive fixed charge, or may be a film having a negative fixed charge.

The fixed charge film 18 preferably includes a semiconductor material or a conductive material having a wider band gap than the semiconductor substrate 11 has. This makes it possible to suppress the generation of a dark current at an interface of the semiconductor substrate 11. Examples of materials of the fixed charge film 18 include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), and aluminum oxynitride (AlOₓN_{y}).

For instance, the logic substrate 20 includes a semiconductor layer 21 including a silicon group, and an interlayer insulating layer 221 in which the semiconductor layer 21 is embedded. In the logic substrate 20, a logic circuit is formed, including the bias voltage applying section 110, a readout circuit that outputs a pixel signal based on a carrier outputted from each unit pixel P of the pixel array section 100A, a vertical drive circuit, a column signal processing circuit, a horizontal drive circuit, and an output circuit.

For instance, the semiconductor layer 21 is separated into a plurality of islands. In each of the islands in the semiconductor layer 21, a plurality of transistors constituting a readout circuit, for example, is formed. Specifically, a p-type or n-type well is formed in each of the islands into which the semiconductor layer 21 is separated, and the p-MOS transistor 211 and the n-MOS transistor 212 that constitute a readout circuit that outputs a pixel signal based on the carriers outputted from the light receiving element 12 are formed on a face opposite to the face facing the sensor substrate 10, for example. The p-MOS transistor 211 has a planar structure, for example, and includes a gate electrode 211G, and a source region 211S and a drain region 211D that are made of p-type semiconductor regions (p⁺). The n-MOS transistor 212 has a planar structure, for example, and includes a gate electrode 212G, and a source region 212S and a drain region 212D that are made of n-type semiconductor regions (n⁺). In the semiconductor layer 21 in which the p-MOS transistor 211 and the n-MOS transistor 212 are formed, a well contact electrode (not illustrated) including an n-type semiconductor region (n⁺) or a p-type semiconductor region (p⁺) is formed for applying a predetermined potential to the well of the semiconductor layer 21.

In the interlayer insulating layer 221, the shield layer 23, to which a predetermined potential is to be applied, is provided on the path coupling the contact layer 15 and each of the p-MOS transistor 211 and the n-MOS transistor 212. The shield layer 23 is used to suppress electrical interference caused by a potential difference between the contact layer 15 and each of the p-MOS transistor 211 and the n-MOS transistor 212. As illustrated in FIG. 1 and FIG. 2(B), for example, the shield layer 23 is placed below the contact layer 15 along the pixel separator 17 over the adjacent unit pixels P, for example. A predetermined potential is applied to the shield layer 23 in accordance with the position in the Z-axis direction, for example. For instance, when the shield layer 23 is formed near the contact layer 15, substantially the same potential as that of the contact layer 15 (e.g.,-20 V) is applied to the shield layer 23. For instance, when the shield layer 23 is formed near the p-MOS transistor 211 or the n-MOS transistor 212, substantially the same potential (e.g., 0 V) as that of the well of the p-MOS transistor 211 or the n-MOS transistor 212 is applied to the shield layer 23, for example.

The shield layer 23 may include a conductive material. The shield layer 23 preferably includes a metal material having light-shielding properties among conductive materials. Specifically, the shield layer 23 may include a metal material such as tungsten (W), aluminum (Al), copper (Cu), cobalt (Co), nickel (Ni), or titanium (Ti), or a silicon compound thereof. In addition to the above-mentioned metal materials and silicides having light-shielding properties, the shield layer 23 may include a material such as silicon, polysilicon, or amorphous silicon that has absorption at a target wavelength. This makes it possible to achieve, in addition to electrical shielding between the contact layer 15 and each of the p-MOS transistor 211 and the n-MOS transistor 212, a light shielding effect for the multiplier 14 of the adjacent unit pixel P against light emission by hot carriers from the p-MOS transistor 211 and the n-MOS transistor 212, as illustrated by the arrows in FIG. 1.

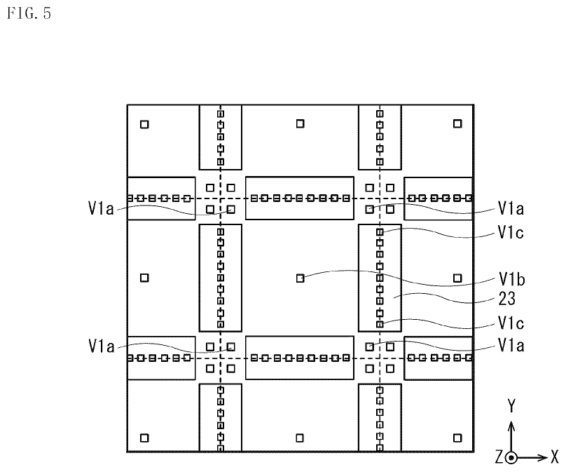

In the interlayer insulating layer 221, one or more wiring layers (e.g., wiring layers 222, 223, and 224), through-vias V1a, V1b, and V1c, and vias V2 and V3 that penetrate the semiconductor layer 21 in the Z-axis direction are further formed. The one or more wiring layers (e.g., the wiring layers 222, 223, and 224) are used to supply a voltage to be applied to the semiconductor substrate 11 and the light receiving element 12, and to extract carriers generated in the light receiving element 12. Specifically, some of wirings of the wiring layers 222, 223, and 224 are electrically coupled to the contact layer 15 and the shield layer 23 through the through-vias V1a and V1c, for example. As illustrated in FIG. 2(B), for example, the via V1c couples the shield layer 23 and the wiring layer 222 near both ends in a longitudinal direction of the shield layer 23 located between adjacent unit pixels P. Note that the via V1c may be intermittently placed to surround the unit pixel P, as illustrated in FIG. 5, for example. Some of the wirings of the wiring layers 222, 223, and 224 are electrically coupled to the contact layer 16 through the via V1b. The one or more wiring layers (e.g., the wiring layer 222, or the wiring layers 222, 223, and 224) are used to supply a voltage to be applied to the semiconductor layer 21 or the p-MOS transistor 211 and n-MOS transistor 212 formed in the semiconductor layer 21. Specifically, some of wirings of the wiring layer 222 are electrically coupled, via a via V2, to the gate electrodes 211G and 212G, source regions 211S and 212S, and drain regions 211D and 212D of the p-MOS transistor 211 and the n-MOS transistor 212, respectively, and to an unillustrated well contact electrode.

For instance, the interlayer insulating layer 221 includes a single layer film including one of silicon oxide (SiOₓ), TEOS, silicon nitride (SiNₓ), and silicon oxynitride (SiOₓN_{y}), or a laminated film including two or more of these materials.

The gate electrodes 211G and 212G and the wiring layer 222 include a material such as aluminum (Al), copper (Cu), or tungsten (W), for example.

For instance, the vias V1a, V1b, V1c, V2, and V3 include a metal material having light-shielding properties, such as tungsten (W), aluminum (Al), copper (Cu), cobalt (Co), nickel (Ni), or titanium (Ti), or a silicon compound thereof.

The semiconductor substrate 11 has a microlens 33 for each unit pixel P on the light receiving face (the second face 11S2) with, for example, a protective layer 31 and a color filter 32 interposed therebetween.

The microlens 33 collects the light incident from above onto the light receiving element 12, and includes silicon oxide (SiOₓ), for example.

### Workings and Effects

The photodetector 1 of the present embodiment includes the shield layer 23, to which a predetermined potential is to be applied, on the path coupling the contact layer 15 (the anode) and the one or more transistors (e.g., the p-MOS transistor 211 and the n-MOS transistor 212). The contact layer 15 is provided on the first face 11S1 of the sensor substrate 10 having the light receiving element 12 including the light receiver 13 and the multiplier 14, and is electrically coupled to the light receiver 13. The one or more transistors are provided in the semiconductor layer 21 constituting the logic substrate 20 stacked on the first face 11S1 of the semiconductor substrate 10. This suppresses electrical interference caused by a potential difference between the contact layer 15 and the one or more transistors (e.g., the p-MOS transistor 211 and the n-MOS transistor 212). This will be described below.

In recent years, a SPAD device has been developed as mentioned above by bonding a separate substrate carrying a transistor onto a SPAD pixel to improve the performance. In this structure having the transistors above the SPAD pixel, characteristics of both the SPAD device and the transistor may fluctuate due to optical or electrical interference between the SPAD device and the transistor.

From an optical point of view, transistor characteristics may fluctuate due to light emission by hot carriers from a multiplier of the SPAD pixel. Also, light emission due to hot carriers from the transistor may affect pixel characteristics. This is particularly an issue for the SPAD pixel, in which even a small number of incident photons are detected as a pulse due to carrier multiplication. From an electrical point of view, high voltages are applied to the anode and the cathode of the SPAD pixel; therefore, a potential difference between the transistor and a high-voltage application point (e.g., the anode) of the SPAD pixel is large. This may cause fluctuations in the characteristics of the transistor and SPAD pixel, as well as deterioration of an interlayer insulating film between the transistors and the SPAD pixel due to the influence of a high electric field.

In contrast, in the present embodiment, the shield layer 23 is provided on the path coupling the contact layer 15 (the anode), which is provided on the first face 11S1 of the sensor substrate 10 and is electrically coupled to the light receiver 13, and the one or more transistors (e.g., the p-MOS transistor 211 and the n-MOS transistor 212) provided on the first face 11S1, and a predetermined potential is to be applied to this shield layer 23. This makes it possible to shield the influence of the electric field caused by the potential difference between the contact layer 15 and the p-MOS transistor 211 or the n-MOS transistor 212.

With this configuration, the photodetector 1 in the present embodiment makes it possible to reduce electrical interference between the contact layer 15 and the p-MOS transistor 211 or the n-MOS transistor 212, thus improving the pixel characteristics.

Next, the following describes a second embodiment and Modification Examples 1 to 7 of the present disclosure, as well as application examples and practical application examples. In the following descriptions, like numerals indicate like components of the first embodiment as described above, and descriptions thereof are omitted as appropriate.

### 2. SECOND EMBODIMENT

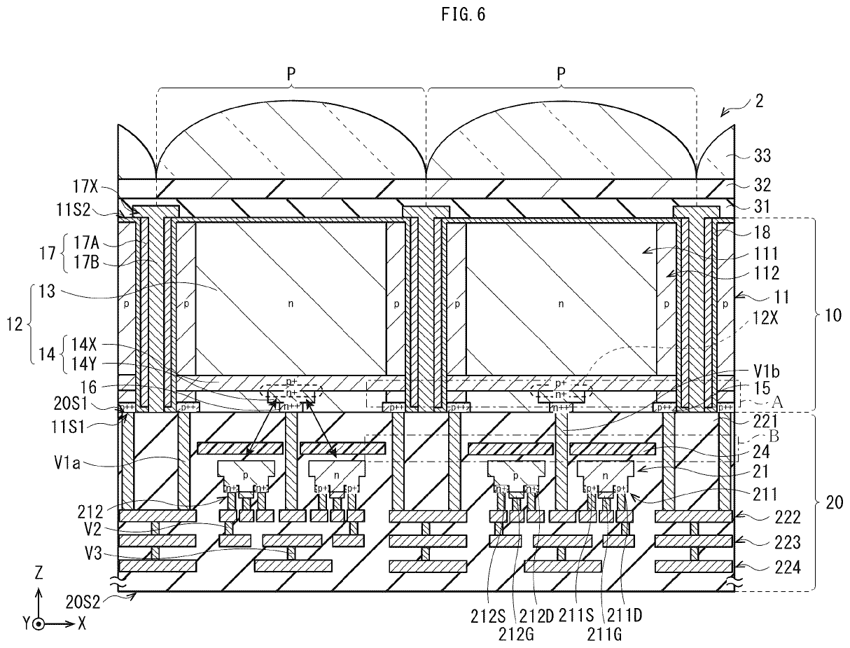

FIG. 6 schematically illustrates an example of a cross-sectional configuration of a photodetector (a photodetector 2) according to the second embodiment of the present disclosure.

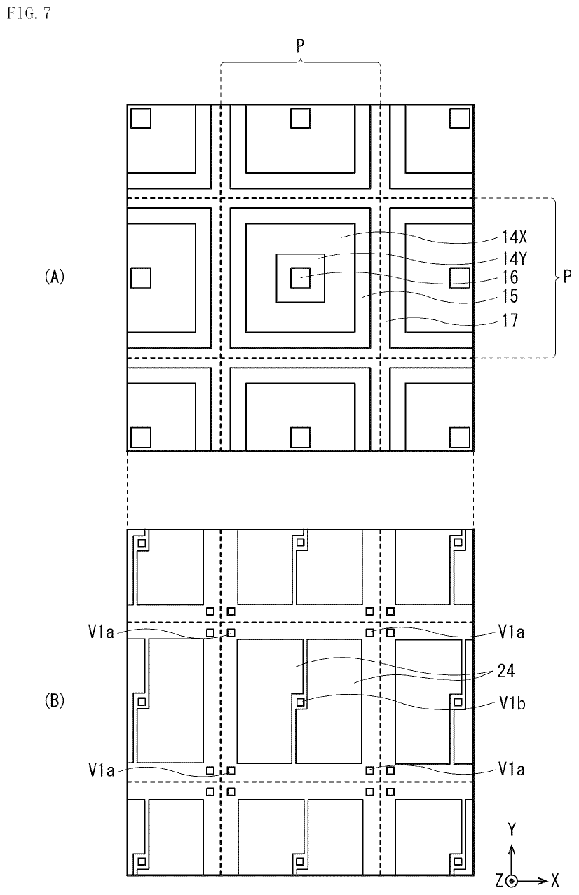

FIG. 7(A) schematically illustrates a planar configuration corresponding to the region A of the photodetector 2 illustrated in FIG. 6. FIG. 7(B) schematically illustrates a planar configuration corresponding to the region B of the photodetector 2 illustrated in FIG. 6. The photodetector 2 is applicable to, for example, a range imaging sensor (e.g., the range imaging device 1000) that measures a distance by a ToF method, an image sensor, and the like.

### Configuration of Photodetector

Similar to the photodetector 1 as described above, the photodetector 2 has the pixel array section 100A in which a plurality of unit pixels P is arranged in an array in row and column directions. Each of the unit pixels P includes the light receiving element 12. The light receiving element 12 has the light receiver 13 and the multiplier 14. Similar to the photodetector 1 described above, the photodetector 2 has the sensor substrate 10 and the logic substrate 20 that are stacked together.

The sensor substrate 10 includes the semiconductor substrate 11 including, for example, silicon, and the light receiver 13 and the multiplier 14 are embedded in the semiconductor substrate 11, for example. The semiconductor substrate 11 includes the contact layer 15 (the anode) and the contact layer 16 (the cathode) on its first face 11S1. The contact layer 15 is electrically coupled to the light receiver 13, and the contact layer 16 is electrically coupled to the multiplier 14. The semiconductor substrate 11 further includes the pixel separator 17 that electrically separates adjacent unit pixels P. The pixel separator 17 is placed between a plurality of unit pixels P adjacent to each other in the row and column directions so as to extend between the first face 11S1 and the second face 11S2 of the semiconductor substrate 11, and is provided in a lattice pattern in a plan view in the entire pixel array section 100A.

For instance, the logic substrate 20 has the semiconductor layer 21 embedded in the interlayer insulating layer 221. In the semiconductor layer 21, a plurality of transistors (e.g., the p-MOS transistor 211 and the n-MOS transistor 212) are formed, which constitute a readout circuit that outputs a pixel signal based on the carrier outputted from the unit pixel P (the light receiving element 12), for example. The logic substrate 20 further has the through-vias V1a and V1b that penetrate the semiconductor layer 21 in the stacking direction (the Z-axis direction) and are electrically coupled to the contact layers 15 and 16, respectively. In the present embodiment, a shield layer 24 is provided on a path coupling the multiplier 14 and each of the p-MOS transistor 211 and the n-MOS transistor 212.

The semiconductor substrate 11 has the first face 11S1 and second face 11S2 opposed to each other. The semiconductor substrate 11 has a p-well (p) common to the plurality of unit pixels P. The semiconductor substrate 11 is provided, for each of the unit pixels P, with the n-type semiconductor region (n) 111 in which the impurity concentration is controlled to n-type, for example, and the n-type semiconductor region 111 constitutes the light receiver 13. The semiconductor substrate 11 is further provided with the p-type semiconductor region (p⁺) 14X and the n-type semiconductor region (n⁺) 14Y, which constitute the multiplier 14 on the side of the first face 11S1. This makes up the light receiving element 12 for each unit pixel P. The semiconductor substrate 11 is further provided with the pixel separator 17 around each unit pixel P to electrically separate adjacent unit pixels P. Between the light receiving element 12 and the pixel separator 17, the p-type semiconductor region (p) 112 having a higher impurity concentration than the p-well is provided.

The light receiving element 12 has a multiplication region (the avalanche multiplication region 12X) that avalanche-multiplies carriers by a high electric field region. As described above, the light receiving element 12 is a SPAD device that enables the formation of the avalanche multiplication region 12X by a large negative voltage applied to the cathode (the contact layer 16), and is capable of avalanche-multiplying electrons generated by the incidence of one photon.

The light receiving element 12 has the light receiver 13 and the multiplier 14.

The light receiver 13 has a photoelectric conversion function of absorbing light incident through the second face 11S2 of the semiconductor substrate 11 and generating carriers corresponding to the amount of the light received. As described above, the light receiver 13 includes the n-type semiconductor region (n) 111 in which the impurity concentration is controlled to n-type, and carriers generated in the light receiver 13 are transferred to the multiplier 14 by a potential gradient.

The multiplier 14 avalanche-multiplies carriers (electrons in the present embodiment) generated in the light receiver 13. For instance, the multiplier 14 includes the p-type semiconductor region (p⁺) 14X having a higher impurity concentration than the p-well (p) and the n-type semiconductor region (n⁺) 14Y having a higher impurity concentration than the n-type semiconductor region (n) 111. The p-type semiconductor region (p⁺) 14X and the n-type semiconductor region (n⁺) 14Y are provided on the side of the first face 11S1, and are stacked in the order of the n-type semiconductor region (n⁺) 14Y and the p-type semiconductor region (p⁺) 14X from the first face 11S1. The p-type semiconductor region (p⁺) 14X has the area in the XY plane direction larger than the area of the n-type semiconductor region (n⁺) 14Y in the XY plane direction, and is placed over the entire surface of the unit pixel P partitioned by the pixel separator 17. The configuration, however, is not limited to this, and the p-type semiconductor region (p⁺) 14X may be formed on the inner side of the p-type semiconductor region (p) 112, for example.

The light receiving element 12 has the avalanche multiplication region 12X formed at the junction between the p-type semiconductor region (p⁺) 14X and the n-type semiconductor region (n⁺) 14Y. The avalanche multiplication region 12X is a high electric field region (a depletion layer) formed at the interface between the p-type semiconductor region (p⁺) 14X and the n-type semiconductor region (n⁺) 14Y by a large negative voltage applied to the cathode. In the avalanche multiplication region 12X, electrons (e⁻) generated by a single photon incident on the light receiving element 12 are multiplied.

The semiconductor substrate 11 is provided with the contact layer 15 and the contact layer 16 on the first face 11S1, and the contact layer 15 includes a p-type semiconductor region (p⁺⁺) that is electrically coupled to the n-type semiconductor region (n) 111 constituting the light receiver 13, and the contact layer 16 includes a n-type semiconductor region (n⁺⁺) that is electrically coupled to the n-type semiconductor region (n⁺) 14Y constituting the multiplier 14. For instance, the contact layer 15 is placed along the inner edge of the unit pixel P. Specifically, as illustrated in FIG. 7(A), the contact layer 15 is placed along the pixel separator 17 to surround the light receiver 13, and is coupled as the anode of the light receiving element 12 to the bias voltage applying section 110. The contact layer 16 is coupled as the cathode to the source terminal of the quenching resistor 120.

The pixel separator 17 electrically separates adjacent unit pixels P, and is provided in a lattice shape in the pixel array section 100A so as to separate the unit pixels P in a plan view, for example. The pixel separator 17 extends between the first face 11S1 and the second face 11S2 of the semiconductor substrate 11, and penetrates the semiconductor substrate 11, for example. For instance, the pixel separator 17 includes the insulating film 17A and the light shielding film 17B embedded in the insulating film 17A. The pixel separator 17 may be provided from the first face 11S1 of the semiconductor substrate 11 or may be formed from the second face 11S2 of the semiconductor substrate 11.

For instance, the insulating film 17A includes silicon oxide (SiOₓ). In one example, the light shielding film 17B includes a metal material having light-shielding properties, such as tungsten (W), aluminum (Al), copper (Cu), cobalt (Co), nickel (Ni), or titanium (Ti), or a silicon compound thereof. In another example, the light shielding film 17B may include polysilicon (Poly-Si). The light-shielding film 17B may include a wide portion 17X formed on the second surface 11S2 of the semiconductor substrate 11 to suppress the incidence of obliquely incident light between adjacent unit pixels P.

On the side and bottom faces of the pixel separator 17 and on the second face 11S2 of the semiconductor substrate 11, a layer having a fixed charge (the fixed charge film 18) may be placed, for example. This fixed charge film 18 may be a film having a positive fixed charge, or may be a film having a negative fixed charge.

The fixed charge film 18 preferably includes a semiconductor material or a conductive material having a wider band gap than the semiconductor substrate 11 has. This makes it possible to suppress the generation of a dark current at the interface of the semiconductor substrate 11. Examples of materials of the fixed charge film 18 include hafnium oxide (HfOₓ), aluminum oxide (A1Oₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), and aluminum oxynitride (A1OₓN_{y}).

For instance, the logic substrate 20 includes the semiconductor layer 21 including a silicon group, and the interlayer insulating layer 221 in which the semiconductor layer 21 is embedded. In the logic substrate 20, a logic circuit is formed, including the bias voltage applying section 110, a readout circuit that outputs a pixel signal based on a carrier outputted from each unit pixel P of the pixel array section 100A, a vertical drive circuit, a column signal processing circuit, a horizontal drive circuit, and an output circuit.

For instance, the semiconductor layer 21 is separated into a plurality of islands. In each of the islands in the semiconductor layer 21, a plurality of transistors constituting a readout circuit, for example, is formed. Specifically, a p-type or n-type well is formed in each of the islands into which the semiconductor layer 21 is separated, and the p-MOS transistor 211 and the n-MOS transistor 212 that constitute a readout circuit that outputs a pixel signal based on the carriers outputted from the light receiving element 12 are formed on the face opposite to the face facing the sensor substrate 10, for example. The p-MOS transistor 211 has a planar structure, for example, and includes the gate electrode 211G, and the source region 211S and the drain region 211D that are made of p-type semiconductor regions (p⁺). The n-MOS transistor 212 has a planar structure, for example, and includes the gate electrode 212G, and the source region 212S and the drain region 212D that are made of n-type semiconductor regions (n⁺). In the semiconductor layer 21 in which the p-MOS transistor 211 and the n-MOS transistor 212 are formed, a well contact electrode (not illustrated) including an n-type semiconductor region (n⁺) or a p-type semiconductor region (p⁺) is formed for applying a predetermined potential to the well of the semiconductor layer 21.

In the interlayer insulating layer 221, a shield layer 24 is provided on the path coupling the multiplier 14 and each of the p-MOS transistor 211 and the n-MOS transistor 212. The shield layer 24 is used to prevent light generated from the multiplier 14 by hot carriers from entering the p-MOS transistor 211 and n-MOS transistor 212 below. Also, the shield layer 24 is used to prevent light generated from the p-MOS transistor 211 and the n-MOS transistor 212 by hot carriers from entering the multiplier 14 above (see the arrows in FIG. 6). The shield layer 24 is placed in an electrically floating state, for example, above the p-MOS transistor 211 and above the n-MOS transistor 212, which face the multiplier 14 and the light receiver 13 extending around the multiplier 14, of each of the plurality of unit pixels P arranged in an array in a plan view, as illustrated in FIG. 6 and FIG. 7(B).

The shield layer 24 preferably includes a metal material having light-shielding properties among conductive materials. Specifically, the shield layer 24 may include a metal material such as tungsten (W), aluminum (Al), copper (Cu), cobalt (Co), nickel (Ni), or titanium (Ti), or a silicon compound thereof. In addition to the above-mentioned metal materials and silicides having light-shielding properties, the shield layer 24 may include a material such as silicon, polysilicon, and amorphous silicon that has absorption at a target wavelength. This makes it possible to provide a shading effect for the multiplier 14 against light emission by hot carriers from the p-MOS transistors 211 and the n-MOS transistors 212.

In the interlayer insulating layer 221, one or more wiring layers (e.g., the wiring layers 222, 223, and 224), the through-vias V1a and V1b, and the vias V2, V3 that penetrate the semiconductor layer 21 in the Z-axis direction are further formed. The one or more wiring layers (e.g., the wiring layers 222, 223, and 224) are used to supply a voltage to be applied to the semiconductor substrate 11 and the light receiving element 12, and to extract carriers generated in the light receiving element 12. Specifically, some of the wirings of the wiring layers 222, 223, and 224 are electrically coupled to the contact layer 15 through the through-via V1a, for example. Some of the wirings of the wiring layers 222, 223, and 224 are electrically coupled to the contact layer 16 through the through-via V1b. The one or more wiring layers (e.g., the wiring layer 222, or the wiring layers 222, 223, and 224) are used to supply a voltage to be applied to the semiconductor layer 21 or the p-MOS transistor 211 and the n-MOS transistor 212 formed in the semiconductor layer 21. Specifically, some of the wirings of the wiring layer 222 are electrically coupled, through the through-via V2, to the gate electrodes 211G and 212G, the source regions 211S and 212S, and the drain regions 211D and 212D of the p-MOS transistor 211 and the n-MOS transistor 212, respectively, and to an unillustrated well contact electrode.

For instance, the interlayer insulating layer 221 includes a single layer film including one of silicon oxide (SiOₓ), TEOS, silicon nitride (SiNₓ), and silicon oxynitride (SiOₓN_{y}), or a laminated film including two or more of these materials.

The gate electrodes 211G and 212G and the wiring layer 222 include a material such as aluminum (Al), copper (Cu), or tungsten (W), for example.

For instance, the through-vias V1a, V1b, V1c, V2, and V3 include a metal material having light-shielding properties, such as tungsten (W), aluminum (Al), copper (Cu), cobalt (Co), nickel (Ni), or titanium (Ti), or a silicon compound thereof.

The semiconductor substrate 11 has the microlens 33 for each unit pixel P on the light receiving face (the second face 11S2) with, for example, the protective layer 31 and the color filter 32 interposed therebetween.

The microlens 33 collects the light incident from above onto the light receiving element 12, and includes silicon oxide (SiOₓ), for example.

### Workings and Effects

The photodetector 2 of the present embodiment includes the shield layer 24 on the path coupling the multiplier 14 and the one or more transistors (e.g., the p-MOS transistor 211 and the n-MOS transistor 212). The multiplier 14 is provided on the first face 11S1 of the sensor substrate 10 having the light receiving element 12 including the light receiver 13 and the multiplier 14. The one or more transistors are provided in the semiconductor layer 21 constituting the logic substrate 20 stacked on the first face 11S1 of the semiconductor substrate 10. This makes it possible to reduce the influence of hot-carrier light emission from the multiplier 14 to the p-MOS transistor 211 and the n-MOS transistor 212. This also makes it possible to reduce the influence of hot-carrier light emission from the p-MOS transistor 211 and the n-MOS transistor 212 to the multiplier 14.

With this configuration, the photodetector 2 in the present embodiment makes it possible to reduce optical interference due to hot-carrier light emission between the contact layer 15 and each of the p-MOS transistor 211 and the n-MOS transistor 212, thus improving the pixel characteristics.

The photodetector 2 of the present embodiment also makes it possible to shield the influence of the electric field caused by the potential difference between the contact layer 15 and the p-MOS transistor 211 or the n-MOS transistor 212. With this configuration, the photodetector 2 in the present embodiment makes it possible to reduce electrical interference between the contact layer 15 and the p-MOS transistor 211 or the n-MOS transistor 212, thus improving the pixel characteristics.

### 3. MODIFICATION EXAMPLES

### 3-1. Modification Example 1

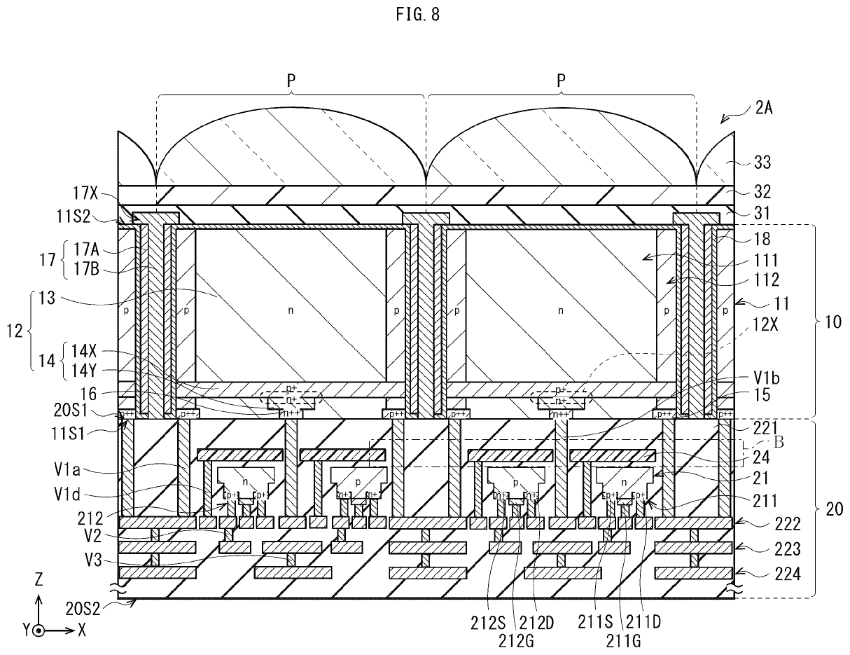

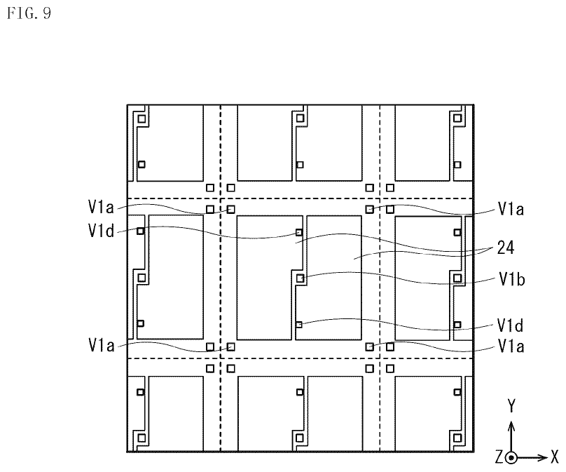

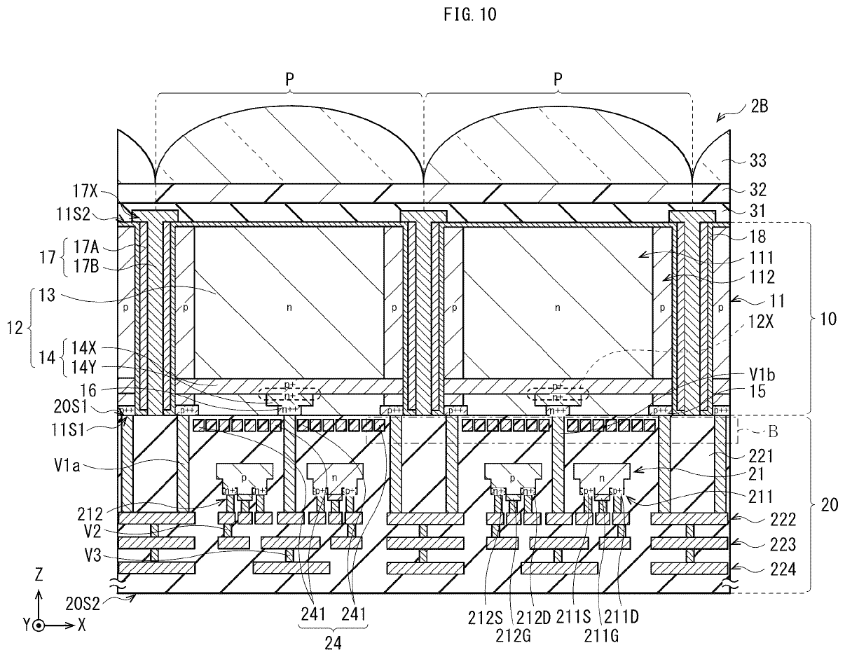

FIG. 8 schematically illustrates an example of a cross-sectional configuration of a photodetector (a photodetector 2A) according to Modification Example 1 of the present disclosure. FIG. 9 schematically illustrates a planar configuration corresponding to the region B of the photodetector 2A illustrated in FIG. 8. Similar to the first and second embodiments as described above, the photodetector 2A is applicable to, for example, a range imaging sensor (e.g., the range imaging device 1000) that measures a distance by a ToF method, an image sensor, and the like.

The photodetector 2A of this modification example is configured so that a predetermined potential is applied to each of the shield layers 24 provided on the path coupling the multiplier 14 and the p-MOS transistor 211 and on the path coupling the multiplier 14 and the n-MOS transistor 212. Substantially the same potentials as those of the wells of the p-MOS transistor 211 and the n-MOS transistor 212 below are applied to these shield layers 24. Specifically, for example, a potential of +3 V is applied to the shield layer 24 above the p-MOS transistor 211 through the through-via V1d. For example, a potential of 0 V is applied to the shield layer 24 above the n-MOS transistor 212 through the through-via V1d.

In this way, the photodetector 2A of this modification example is configured so that a predetermined potential is applied to each of the shield layers 24 provided on the path coupling the multiplier 14 and the p-MOS transistor 211 and on the path coupling the multiplier 14 and the n-MOS transistor 212. This makes it possible to reduce the influence of hot-carrier light emission from the multiplier 14 to the p-MOS transistor 211 and the n-MOS transistor 212, or from the p-MOS transistor 211 and the n-MOS transistor 212 to the multiplier 14. Thus, it is possible to further improve the pixel characteristics.

### 3-2. Modification Example 2

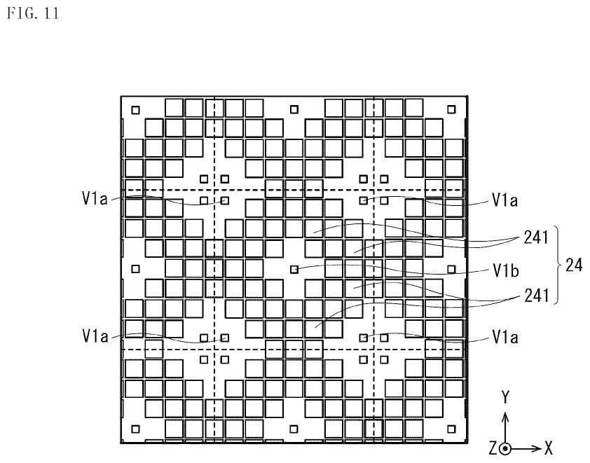

FIG. 10 schematically illustrates an example of a cross-sectional configuration of a photodetector (a photodetector 2B) according to Modification Example 1 of the present disclosure. FIG. 11 schematically illustrates a planar configuration corresponding to the region B of the photodetector 2B illustrated in FIG. 10. Similar to the first and second embodiments as described above, the photodetector 2B is applicable to, for example, a range imaging sensor (e.g., the range imaging device 1000) that measures a distance by a ToF method, an image sensor, and the like.

The photodetector 2B of this modification example includes the shield layer 24 including a plurality of electrically floating shields 241 on the path coupling the multiplier 14 and each of the p-MOS transistors 211 and the n-MOS transistors 212. The plurality of shields 241 is arranged like islands that are placed discretely at a predetermined pitch.

In this way, the photodetector 2B of this modification example includes a refractive-index gradient structure on the path coupling the multiplier 14 and each of the p-MOS transistor 211 and the n-MOS transistor 212. This allows light generated from the multiplier 14 by hot carriers, for example, to be diffused by a refractive index difference between the interlayer insulating layer 221 and the plurality of shields 241. Thus, similarly to the second embodiment as described above, this modification example also makes it possible to improve the pixel characteristics.

### 3-3. Modification Example 3

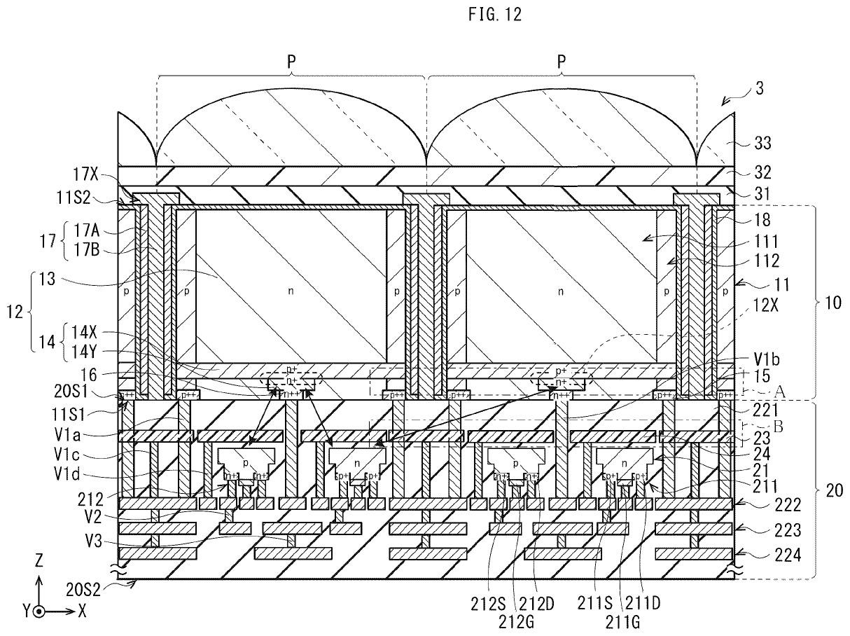

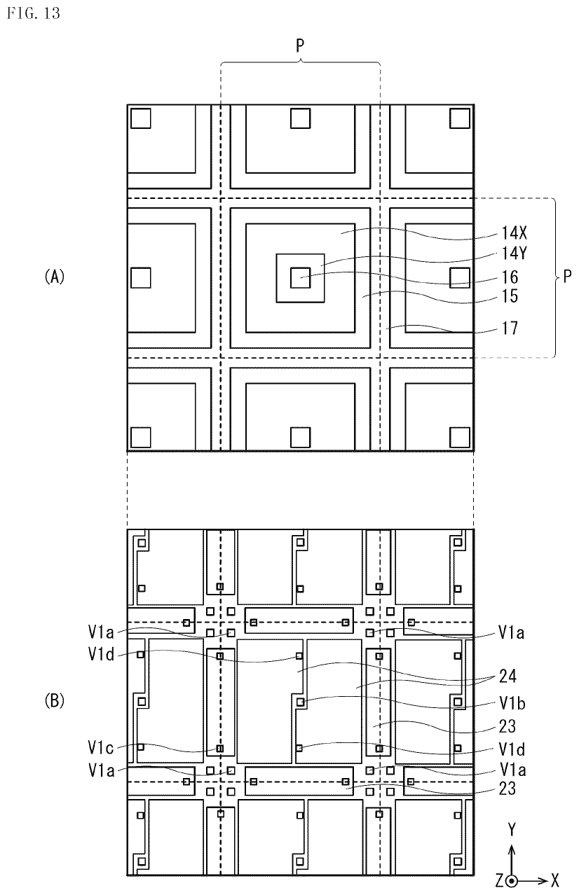

FIG. 12 schematically illustrates an example of a cross-sectional configuration of a photodetector (a photodetector 3) according to Modification Example 3 of the present disclosure.

FIG. 13(A) schematically illustrates a planar configuration corresponding to the region A of the photodetector 3 illustrated in FIG. 12. FIG. 13(B) schematically illustrates a planar configuration corresponding to the region B of the photodetector 3 illustrated in FIG. 12. Similar to the first and second embodiments as described above, the photodetector 3 is applicable to, for example, a range imaging sensor (e.g., the range imaging device 1000) that measures a distance by a ToF method, an image sensor, and the like.

The photodetector 3 of this modification example is a combination of the photodetector 1 of first embodiment described above and the photodetector 2A of Modification Example 1 described above. Specifically, the photodetector 3 has the shield layer 23 on the path coupling the contact layer 15 and each of the p-MOS transistor 211 and the n-MOS transistor 212, and the shield layer 24 on the path coupling the multiplier 14 and each of the p-MOS transistors 211 and the n-MOS transistors 212. The shield layers 23 and 24 are formed in the same layer in the interlayer insulating layer 221.

Here, the shield layer 23 corresponds to one specific example of a “first shield layer” in Modification Example 3 of the present disclosure, and the shield layer 24 corresponds to one specific example of a “second shield layer” in Modification Example 3 of the present disclosure.

A predetermined potential is applied to the shield layer 23 and the shield layer 24 through the through-vias V1c and V1d, respectively. Specifically, substantially the same potential (e.g., +3 V or 0 V) as that of the well of the p-MOS transistor 211 or the n-MOS transistor 212 is applied to the shield layer 23 and the shield layer 24 through the through-vias V1c and V1d, respectively.

In this way, the photodetector 3 of this modification example has the shield layer 23 on the path coupling the contact layer 15 and each of the p-MOS transistors 211 and the n-MOS transistors 212, and the shield layer 24 on the path coupling the multiplier 14 and each of the p-MOS transistors 211 and n-MOS transistors 212 and the shield layers 23 and 24 are formed in the same layer. Substantially the same potential (e.g., +3 V or 0 V) as that of the well of the p-MOS transistor 211 or the n-MOS transistor 212 is applied to the shield layers 23 and 24, for example. This makes it possible to achieve, in addition to electrical shielding between the contact layer 15 and each of the p-MOS transistor 211 and the n-MOS transistor 212, reduction of optical interference due to hot-carrier light emission from the multiplier 14 to the p-MOS transistor 211 and the n-MOS transistor 212, and from the p-MOS transistor 211 and the n-MOS transistor 212 to the multiplier 14. The photodetector 3 also makes it possible to reduce optical interference between adjacent unit pixels P. Thus, it is possible to further improve the pixel characteristics, as compared with the first and second embodiments described above.

### 3-4. Modification Example 4

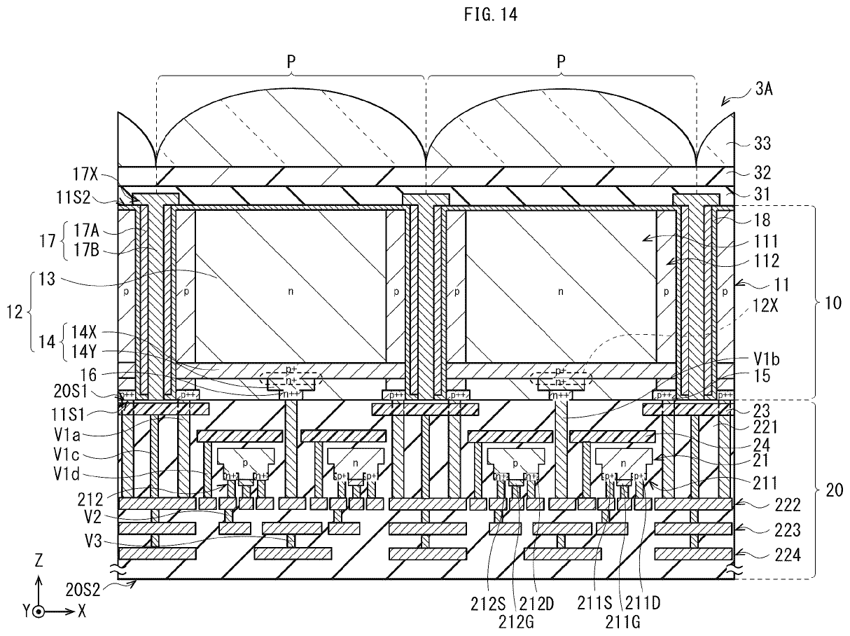

FIG. 14 schematically illustrates an example of a cross-sectional configuration of a photodetector (a photodetector 3A) according to Modification Example 4 of the present disclosure. Similar to the first and second embodiments as described above, the photodetector 3A is applicable to, for example, a range imaging sensor (e.g., the range imaging device 1000) that measures a distance by a ToF method, an image sensor, and the like.

The above Modification Example 3 shows an example where the shield layer 23 on the path coupling the contact layer 15 and each of the p-MOS transistors 211 and the n-MOS transistors 212, and the shield layer 24 on the path coupling the multiplier 14 and each of the p-MOS transistors 211 and the n-MOS transistors 212 are formed in the same layer, and the present disclosure is not limited to this. The photodetector 3A of this modification example has the shield layer 23 and the shield layer 24 formed in different layers from each other. Specifically, the photodetector 3A is configured so that the shield layer 23 is formed near the contact layer 15 and the shield layer 24 is formed near the p-MOS transistor 211 and the n-MOS transistor 212.

A predetermined potential is applied to the shield layer 23 and the shield layer 24 through the through-vias V1c and Vld, respectively. Specifically, substantially the same potential as that of the contact layer 15 (e.g.,-20 V) is applied to the shield layer 23 through the through-via V1c. Substantially the same potential (e.g., +3 V or 0 V) as that of the well of the p-MOS transistor 211 or the n-MOS transistor 212 is applied to the shield layer 24 though the through-via V1d.

In this manner, the photodetector 3A of this modification example is configured so that the shield layer 23 is formed near the contact layer 15, and substantially the same potential as that of the contact layer 15 is applied to the shield layer 23. The shield layer 24 is formed near each of the p-MOS transistor 211 and the n-MOS transistor 212, and substantially the same potential as that of the well of the p-MOS transistor 211 or the n-MOS transistor 212 is applied to the shield layer 24. This makes it possible to achieve, in addition to electrical shielding between the contact layer 15 and each of the p-MOS transistor 211 and the n-MOS transistor 212, reduction of optical interference due to hot-carrier light emission from the multiplier 14 to the p-MOS transistor 211 and n-MOS transistor 212, and from the p-MOS transistor 211 and n-MOS transistor 212 to the multiplier 14. The photodetector 3A also has an improved effect of electrically shielding between the contact layer 15 and each of the p-MOS transistor 211 and the n-MOS transistor 212. Thus, it is possible to further improve the pixel characteristics, as compared with Modification Example 3 described above.

### 3-5. Modification Example 5

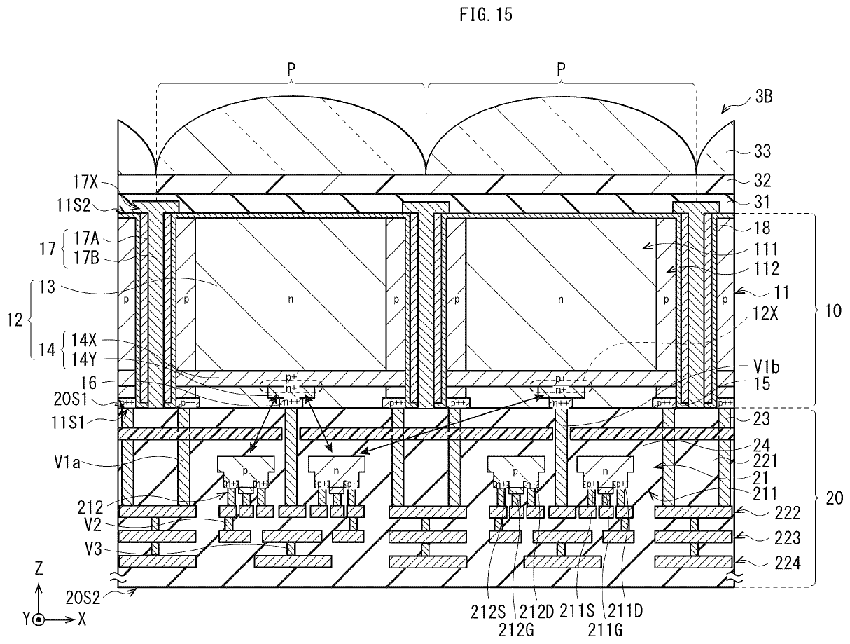

FIG. 15 schematically illustrates an example of a cross-sectional configuration of a photodetector (a photodetector 3B) according to Modification Example 5 of the present disclosure.

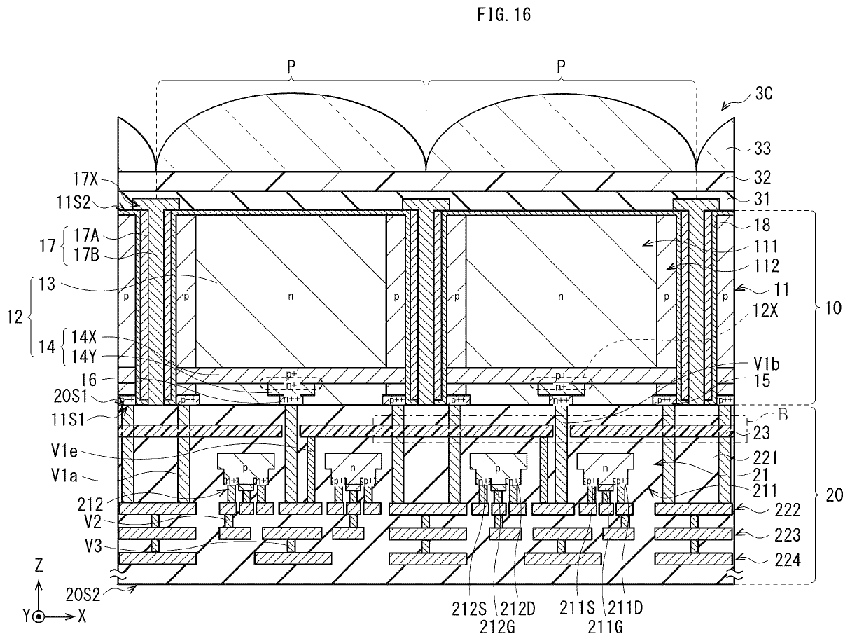

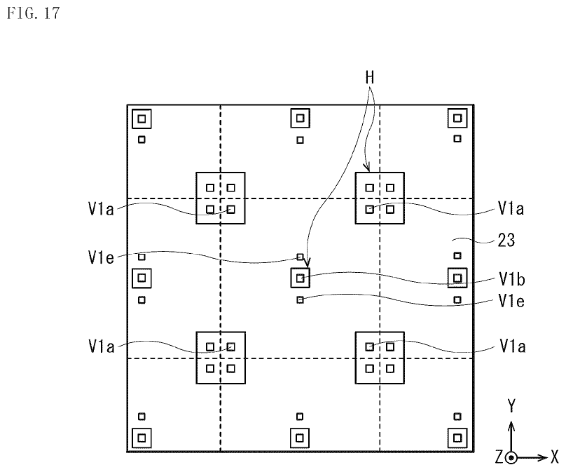

FIG. 16 schematically illustrates another example of a cross-sectional configuration of a photodetector (a photodetector 3C) according to Modification Example 5 of the present disclosure. FIG. 17 schematically illustrates a planar configuration corresponding to the region B of the photodetector 3C illustrated in FIG. 16. Similar to the first and second embodiments as described above, the photodetectors 3B and 3C are applicable to, for example, a range imaging sensor (e.g., the range imaging device 1000) that measures a distance by a ToF method, an image sensor, and the like.

The photodetectors 3B and 3C are configured so that the shield layer 23 is continuously formed over the plurality of unit pixels P placed in an array in the pixel array section 100A. Openings H are formed in the shield layer 23 to avoid the vias V1a and V1b, which are electrically coupled to the contact layers 15 and 16, respectively. The shield layer 23 of the photodetector 3B is electrically floating. A predetermined potential (e.g., 0 V) is applied to the shield layer 23 of the photodetector 3C through a through-via V1e.

Thus, the photodetectors 3B and 3C of this modification example each include the shield layer 23 that is continuously formed over the plurality of unit pixels P placed in an array in the pixel array section 100A. This makes it possible to reduce optical interference caused by hot-carrier light emission within the unit pixel P and between adjacent unit pixels P from the multiplier 14 to the p-MOS transistor 211 and the n-MOS transistor 212 and from the p-MOS transistor 211 and the n-MOS transistor 212 to the multiplier 14. Thus, it is possible to further improve the pixel characteristics, as compared with the second embodiment described above.

Furthermore, the photodetector 3C of this modification example is configured so that a predetermined potential is applied to the shield layer 23. This makes it possible to shield the influence of the electric field caused by the potential difference between the contact layer 15 and the p-MOS transistor 211 or the n-MOS transistor 212. Thus, it is possible to further improve the pixel characteristics.

### 3-6. Modification Example 6

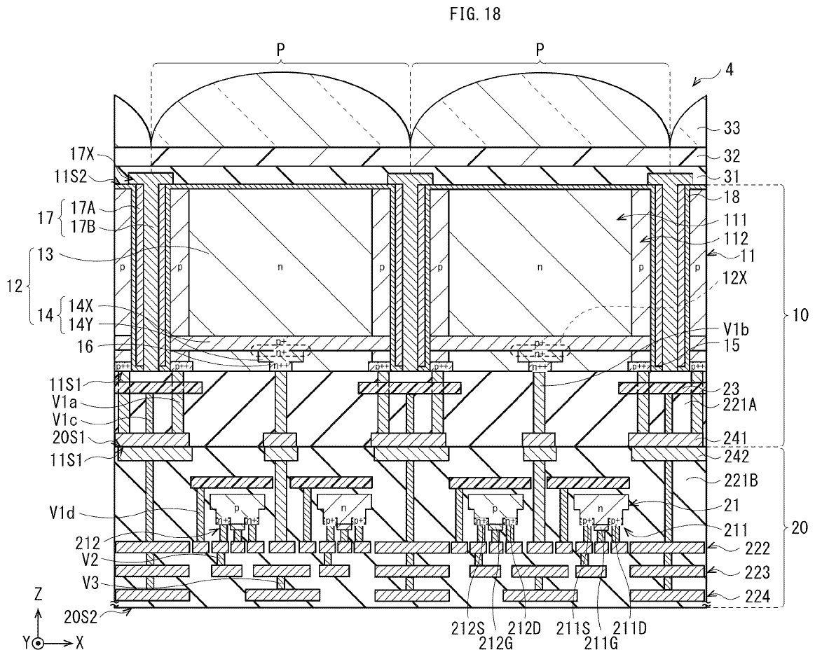

FIG. 18 schematically illustrates an example of a cross-sectional configuration of a photodetector (a photodetector 4) according to Modification Example 6 of the present disclosure. Similar to the first and second embodiments as described above, the photodetector 4 is applicable to, for example, a range imaging sensor (e.g., the range imaging device 1000) that measures a distance by a ToF method, an image sensor, and the like.

The photodetector 4 has a wiring layer on the side of the first face 11S1 of the sensor substrate 10, and the sensor substrate 10 and the logic substrate 20 are stacked in a face-to-back manner. For instance, the sensor substrate 10 and the logic substrate 20 are electrically coupled by hybrid bonding. Specifically, the sensor substrate 10 and the logic substrate 20 are electrically coupled through pads 242 and 243 including copper (Cu), for example, embedded in opposite faces thereof. In other words, the sensor substrate 10 and the logic substrate 20 are electrically coupled by Cu—Cu bonding.

In the photodetector 4, the shield layer 23 is formed on a side of the sensor substrate 10 and the shield layer 24 is formed on a side of the logic substrate 20, and a predetermined potential is applied to the shield layers 23 and 24 through the through-vias V1c and Vld, respectively.

This configuration also makes it possible to obtain effects similar to those in the above first and second embodiments.

### 3-7. Modification Example 7

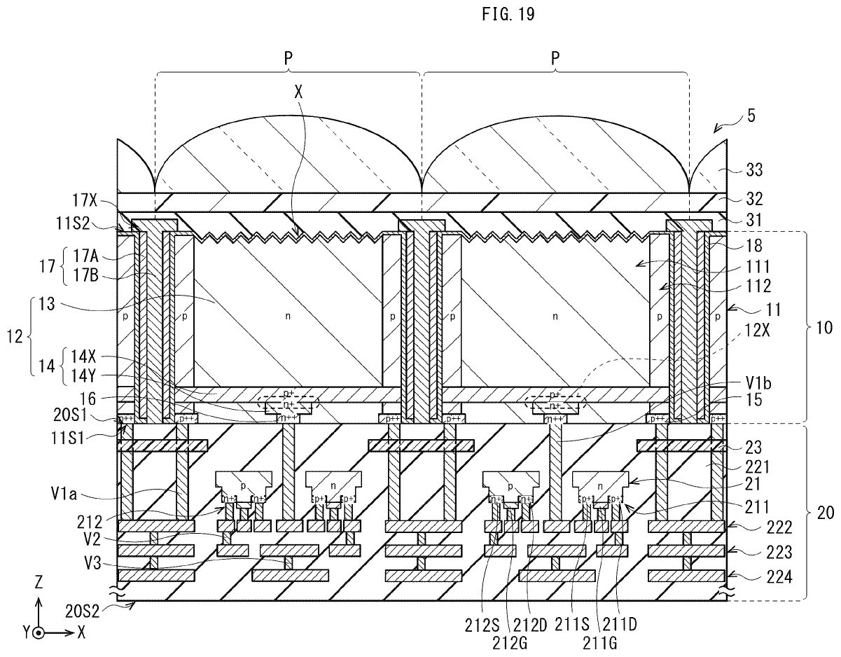

FIG. 19 schematically illustrates an example of a cross-sectional configuration of a photodetector (a photodetector 5) according to Modification Example 7 of the present disclosure. Similar to the first and second embodiments as described above, the photodetector 5 is applicable to, for example, a range imaging sensor (e.g., the range imaging device 1000) that measures a distance by a ToF method, an image sensor, and the like.

The photodetector 5 has a concave-convex structure X (a rig structure) formed on the second face 11S2, serving as a light incident surface, of the semiconductor substrate 11.

In this way, the photodetector 5 of this modification example has a rig structure formed on the second face 11S2 serving as the light incident surface. This makes it possible to improve photoelectric conversion efficiency in the light receiving element 12 in addition to the effects of the first and second embodiments described above.

### Other Modification Examples

In the above embodiments and Modification Examples 1 to 7, the present technology has been described with use of an example in which a plurality of transistors (e.g., the p-MOS transistor 211 and the n-MOS transistor 212) constituting a readout circuit are placed at positions opposite to the unit pixels P. The present technology is not limited to this. The present technology also makes it possible to obtain similar effects in a photodetector in which, in addition to the readout circuit, a circuit or an element other than a pixel readout circuit, such as a transistor that controls circuit driving or selects a pixel, is placed at a position opposite to the unit pixels P.

### 4. APPLICATION EXAMPLES

FIG. 20 illustrates an example of a schematic configuration of the range imaging device 1000 that is an electronic device equipped with a photodetector according to any of the above-mentioned embodiments and Modification Examples 1 to 7 (e.g., the photodetector 1).

The range imaging device 1000 includes a light source 1100, an optical system 1200, the photodetector 1, an image processing circuit 1300, a monitor 1400, and a memory 1500.

The range imaging device 1000 is capable of obtaining a distance image corresponding to a distance to an irradiated object 2000 by receiving light (modulated light or pulsed light) that is projected from the light source 1100 toward the irradiated object 2000 and reflected from a surface of the irradiated object 2000.

The optical system 1200 is configured to have one or more lenses, and guide image light (incident light) from the irradiated object 2000 to the photodetector 1, thus forming an image on a light receiving surface (a sensor section) of the photodetector 1.

The image processing circuit 1300 performs image processing to form a distance image on the basis of a distance signal supplied from the photodetector 1, and the distance image (image data) obtained by this image processing is supplied to the monitor 1400 for display, or supplied to the memory 1500 for storage (recording).

The range imaging device 1000 configured in this manner includes the above-mentioned photodetector (e.g., the photodetector 1). This makes it possible to calculate the distance to the irradiated object 2000 on the basis of only a light receiving signal from the highly stable unit pixels P, and to generate a highly accurate distance image. That is, the range imaging device 1000 allows a more accurate distance image to be obtained.

### 5. PRACTICAL APPLICATION EXAMPLES

### Practical Application Example to Endoscopic Surgery System

The technology according to the present disclosure (present technology) is applicable to various products. For example, the technology according to the present disclosure may be applied to an endoscopic surgery system.

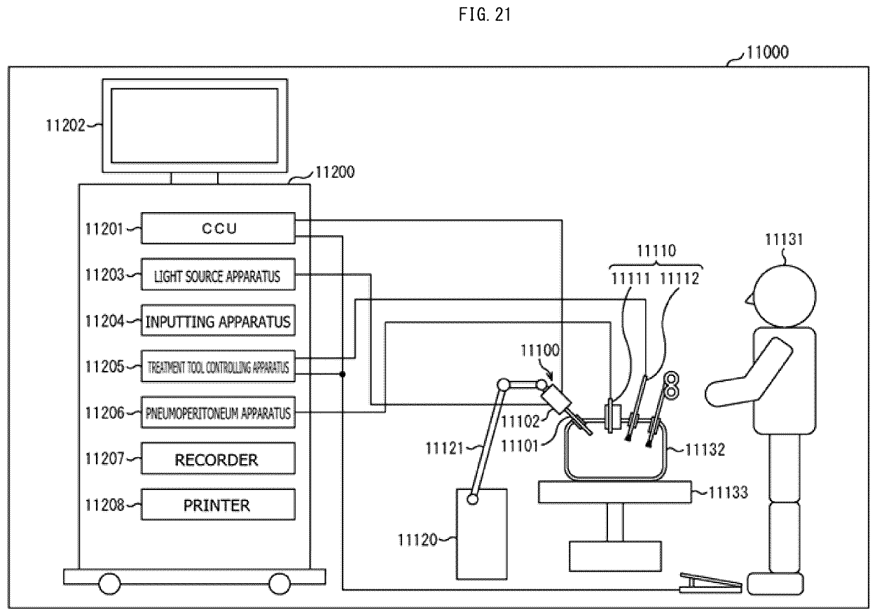

FIG. 21 is a view depicting an example of a schematic configuration of an endoscopic surgery system to which the technology according to an embodiment of the present disclosure (present technology) can be applied.

In FIG. 21, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

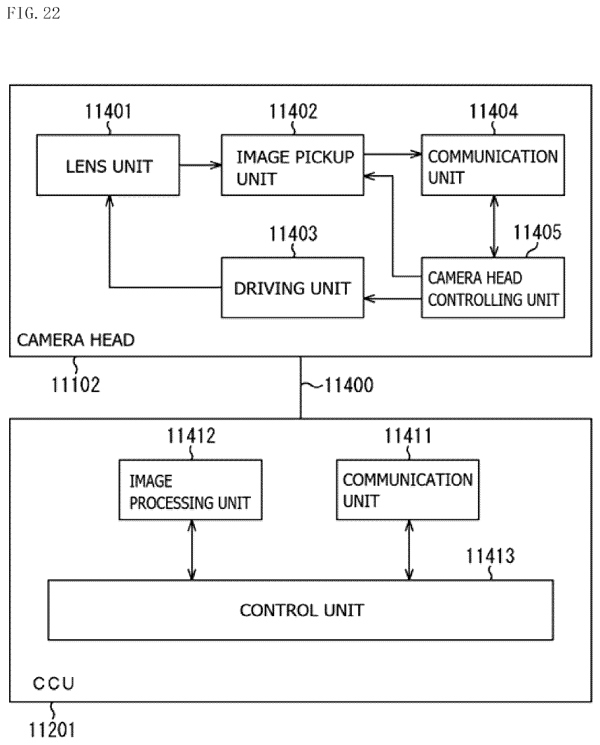

FIG. 22 is a block diagram depicting an example of a functional configuration of the camera head 11102 and the CCU 11201 depicted in FIG. 21.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to the present disclosure may be applied. The technology according to the present disclosure may be applied to, for example, the image pickup unit 11402 among the configurations described above. The application of the technology according to the present disclosure to the image pickup unit 11402 makes it possible to improve detection accuracy.

It is to be noted that although the endoscopic surgery system has been described as an example here, the technology according to the present disclosure may also be applied to, for example, a microscopic surgery system, and the like.

### Practical Application Example to Mobile Body

The technology according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, a robot, a construction machine, or an agricultural machine (tractor).

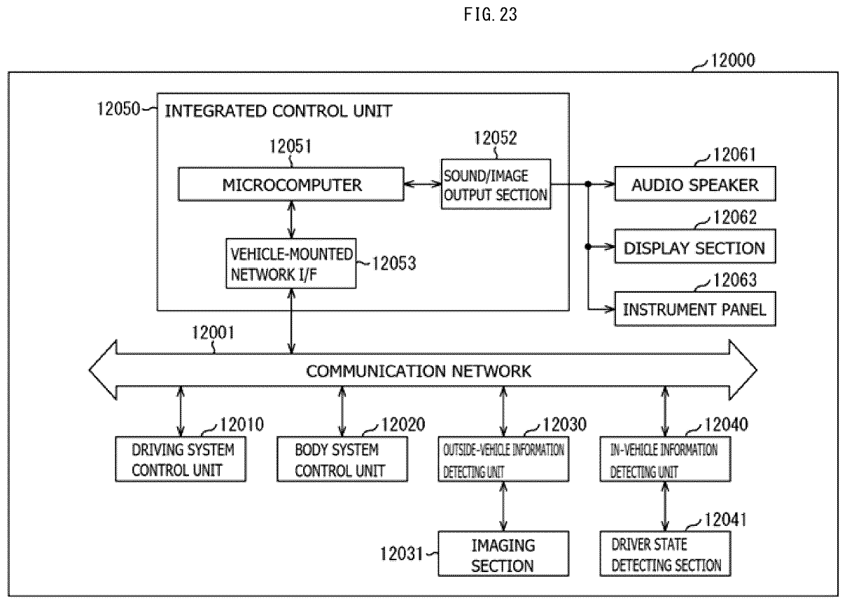

FIG. 23 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 23, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display and a head-up display.

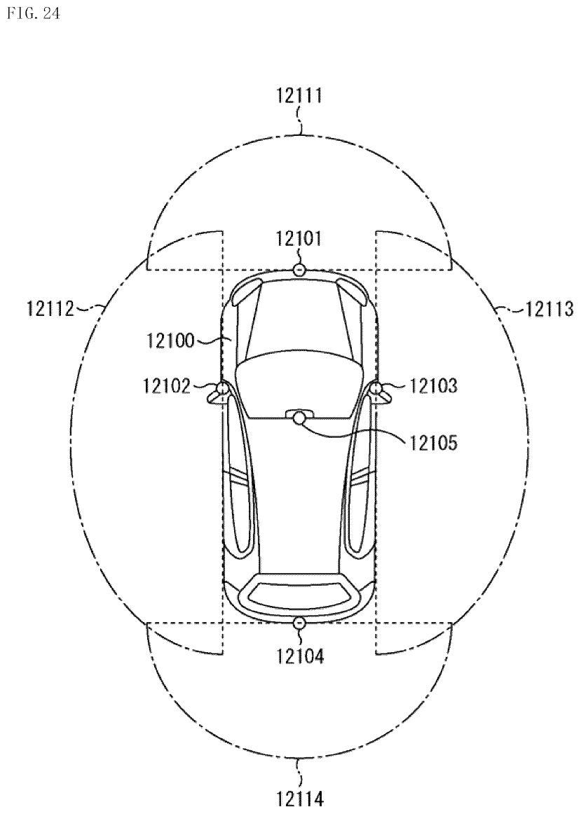

FIG. 24 is a diagram depicting an example of the installation position of the imaging section 12031.

In FIG. 24, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 24 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the vehicle control system, to which the technology according to the present disclosure may be applied. The technology according to the present disclosure may be applied to the imaging section 12031 among the configurations described above. Specifically, the photodetector (e.g., the photodetector 1) according to any of the above embodiments and Modification Examples 1 to 7 thereof is applicable to the imaging section 12031. The application of the technology according to the present disclosure to the imaging section 12031 makes it possible to obtain a high-definition shot image with less noise. This makes it possible to perform highly accurate control with use of the shot image in the mobile body control system.

Although the description has been given with reference to the embodiments, Modification Examples 1 to 7, the application examples, and the practical application examples, the present technology is not limited to the embodiments and the like described above, and may be modified in a variety of ways. For example, the photodetector of the present disclosure does not have to include all of the components described in the above embodiments and the like, and may include other layers. For instance, in a case where the photodetector 1 is to detect light other than visible light (e.g., near-infrared light (IR)), the color filter 32 may be omitted.

Further, a polarity of the semiconductor region constituting the photodetector according to the present disclosure may be inverted. Further, in the photodetector according to the present disclosure, holes may serve as the signal charge.

Furthermore, as long as the photodetector according to the present disclosure is in a state in which the avalanche multiplication occurs by applying a reverse-bias between the anode and the cathode, the respective potentials are not limited.

In addition, the above embodiment and the like exemplify the semiconductor substrate 11 including silicon; however, the semiconductor substrate 11 may include, for example, germanium (Ge), or a compound semiconductor (e.g., silicon germanium (SiGe)) of silicon (Si) and germanium (Ge).

Furthermore, the shape of the unit pixel P is not limited to the rectangular shape. For example, the unit pixel P may have an octagonal shape, and the plurality of unit pixels P constituting the pixel array section 100A may be arranged in a honeycomb pattern.

The effects described herein are mere examples. The present disclosure may include any effects other than those described herein, or may further include other effects in addition to those described herein.

The present disclosure may have the following configurations. According to the present technology having the following configurations, a shield layer is provided on a path coupling a first contact layer provided on a first face of a first substrate and electrically coupled to a light receiver, and one or more transistors provided in a semiconductor layer constituting a second substrate stacked on the first face. This suppresses electrical interference caused by a potential difference between the first contact layer and the one or more transistors. Thus, it is possible to improve pixel characteristics.
(1)

A photodetector including:
a first substrate having a first face and a second face opposed to each other, and having a pixel array section in which a plurality of pixels is arranged in an array in an in-plane direction;
a second substrate stacked on a side of the first face of the first substrate, and having a semiconductor layer provided with one or more transistors;
a light receiving element provided inside the first substrate for each of the pixels, and having a light receiver and a multiplier, the light receiver that generates carriers corresponding to an amount of received light by photoelectric conversion, the multiplier that avalanche-multiplies the carriers generated by the light receiver;
a first contact layer that is provided on the first face of the first substrate, and is electrically coupled to the light receiver; and
a shield layer that is provided on a path coupling the first contact layer and the one or more transistors, and to which a predetermined potential is to be applied.
(2)

The photodetector according to (1), in which the shield layer is provided across the pixels adjacent to each other.
(3)

The photodetector according to (1) or (2), in which
the first contact layer is formed along an inner edge of each of the plurality of pixels, and
the shield layer is provided between the pixels adjacent to each other.
(4)

The photodetector according to (3), in which the shield layer is coupled to one or more through-wires that penetrate the semiconductor layer of the second substrate.
(5)

The photodetector according to (3) or (4), in which
the shield layer is coupled to a plurality of through-wires that penetrates the semiconductor layer of the second substrate, and
the plurality of through-wires surrounds each of the plurality of pixels.
(6)

The photodetector according to any one of (1) to (5), in which the shield layer is provided above the one or more transistors.
(7)

The photodetector according to (6), in which the shield layer includes a plurality of island-shaped shields placed discretely.
(8)

The photodetector according to any one of (1) to (7), in which the shield layer is provided continuously over the plurality of pixels.
(9)

The photodetector according to any one of (1) to (8), in which the shield layer includes a first shield layer and a second shield layer, the first shield layer provided between the pixels adjacent to each other, the second shield layer provided above the one or more transistors.
(10)

The photodetector according to (9), in which the first shield layer and the second shield layer are formed in a same layer.
(11)

The photodetector according to (10), in which substantially a same potential as a potential to be applied to a well of the semiconductor layer provided in the second substrate is applied to the first shield layer and the second shield layer.
(12)

The photodetector according to any one of (9) to (11), in which the first shield layer is formed closer to the first substrate than the second shield layer.
(13)

The photodetector according to (12), in which substantially a same potential as a potential to be applied to the first contact layer is applied to the first shield layer.
(14)

The photodetector according to (12) or (13), in which substantially a same potential as a potential to be applied to a well of the semiconductor layer provided in the second substrate is applied to the second shield layer.
(15)

The photodetector according to any one of (1) to (14), further including a second contact layer that is provided on the first face of the first substrate and is electrically coupled to the multiplier.
(16)

The photodetector according to any one of (1) to (15), in which the first substrate and the second substrate are electrically coupled by hybrid bonding.
(17)

The photodetector according to any one of (1) to (16), in which the first substrate and the second substrate are electrically coupled by Cu—Cu bonding.
(18)

The photodetector according to any one of (1) to (17), in which the one or more transistors constitute a readout circuit that outputs a pixel signal based on the carrier outputted from the light receiving element.
(19)

The photodetector according to any one of (1) to (18), further including a pixel separator that is provided between adjacent ones of the plurality of pixels to extend between the first face and the second face of the first substrate, and electrically separates the adjacent ones of the plurality of pixels, in which
the first contact layer is provided along the pixel separator around each of the plurality of pixels.
(20)

A photodetector including:
a first substrate having a first face and a second face opposed to each other, and having a pixel array section in which a plurality of pixels is arranged in an array in an in-plane direction;
a second substrate stacked on a side of the first face of the first substrate, and having a semiconductor layer provided with one or more transistors;
a light receiving element provided inside the first substrate for each of the pixels, and having a light receiver and a multiplier, the light receiver that generates carriers corresponding to an amount of received light by photoelectric conversion, the multiplier that avalanche-multiplies the carriers generated by the light receiver; and
a shield layer provided on a path coupling the multiplier and the one or more transistors.

The present application claims the benefit of Japanese Priority Patent Application JP2023-058995 filed with the Japan Patent Office on Mar. 31, 2023, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A photodetector, comprising:
a first substrate having a first face and a second face opposed to each other, and having a pixel array section in which a plurality of pixels is arranged in an array in an in-plane direction;
a second substrate stacked on a side of the first face of the first substrate, and having a semiconductor layer provided with one or more transistors;
a light receiving element provided inside the first substrate for each of the pixels, and having a light receiver and a multiplier, the light receiver that generates carriers corresponding to an amount of received light by photoelectric conversion, the multiplier that avalanche-multiplies the carriers generated by the light receiver;
a first contact layer that is provided on the first face of the first substrate, and is electrically coupled to the light receiver; and
a shield layer that is provided on a path coupling the first contact layer and the one or more transistors, and to which a predetermined potential is to be applied.

2. The photodetector according to claim 1, wherein the shield layer is provided across the pixels adjacent to each other.

3. The photodetector according to claim 1, wherein
the first contact layer is formed along an inner edge of each of the plurality of pixels, and
the shield layer is provided between the pixels adjacent to each other.

4. The photodetector according to claim 3, wherein the shield layer is coupled to one or more through-wires that penetrate the semiconductor layer of the second substrate.

5. The photodetector according to claim 3, wherein
the shield layer is coupled to a plurality of through-wires that penetrates the semiconductor layer of the second substrate, and
the plurality of through-wires surrounds each of the plurality of pixels.

6. The photodetector according to claim 1, wherein the shield layer is provided above the one or more transistors.

7. The photodetector according to claim 6, wherein the shield layer includes a plurality of island-shaped shields placed discretely.

8. The photodetector according to claim 1, wherein the shield layer is provided continuously over the plurality of pixels.

9. The photodetector according to claim 1, wherein the shield layer includes a first shield layer and a second shield layer, the first shield layer provided between the pixels adjacent to each other, the second shield layer provided above the one or more transistors.

10. The photodetector according to claim 9, wherein the first shield layer and the second shield layer are formed in a same layer.

11. The photodetector according to claim 10, wherein substantially a same potential as a potential to be applied to a well of the semiconductor layer provided in the second substrate is applied to the first shield layer and the second shield layer.

12. The photodetector according to claim 9, wherein the first shield layer is formed closer to the first substrate than the second shield layer.

13. The photodetector according to claim 12, wherein substantially a same potential as a potential to be applied to the first contact layer is applied to the first shield layer.

14. The photodetector according to claim 12, wherein substantially a same potential as a potential to be applied to a well of the semiconductor layer provided in the second substrate is applied to the second shield layer.

15. The photodetector according to claim 1, further comprising a second contact layer that is provided on the first face of the first substrate and is electrically coupled to the multiplier.

16. The photodetector according to claim 1, wherein the first substrate and the second substrate are electrically coupled by hybrid bonding.

17. The photodetector according to claim 1, wherein the first substrate and the second substrate are electrically coupled by Cu—Cu bonding.

18. The photodetector according to claim 1, wherein the one or more transistors constitute a readout circuit that outputs a pixel signal based on the carrier outputted from the light receiving element.

19. The photodetector according to claim 1, further comprising a pixel separator that is provided between adjacent ones of the plurality of pixels to extend between the first face and the second face of the first substrate, and electrically separates the adjacent ones of the plurality of pixels, wherein
the first contact layer is provided along the pixel separator around each of the plurality of pixels.
